(19) United States
(12) Patent Application Publication
(10) Pub. No.: US 2026/0020454 A1
(43) Pub. Date: Jan. 15, 2026

(54) DISPLAY PANEL AND DISPLAY APPARATUS

(71) Applicant: BOE Technology Group Co., Ltd., Beijing (CN)

(72) Inventors: Qing Ma, Beijing (CN); Mengwen Jia, Beijing (CN); Jie Cao, Beijing (CN)

(73) Assignee: BOE Technology Group Co., Ltd., Beijing (CN)

(21) Appl. No.: 18/994,714

(22) PCT Filed: Apr. 18, 2024
(86) PCT No.: PCT/CN2024/088671

§ 371 Date: Jan. 15, 2025

(30) Foreign Application Priority Data
May 31, 2023 (CN) 202310637613.5

(51) Int. Cl. H10K 59/131; H01Q 1/24; H01Q 1/38; H01Q 13/10; H10K 59/80

(52) U.S. Cl. CPC H10K 59/131; H01Q 1/243; H01Q 1/38; H01Q 13/10; H10K 59/873; H10K 59/8794

(57) ABSTRACT

The present disclosure provides a display panel including a stack of: a substrate, including a display area and a non-display area; a first conductive layer, including a first conductive part located in the non-display area, wherein the first conductive part is provided with an opening, and the opening penetrates through the first conductive part along a thickness direction; a second conductive layer, including a feed line, wherein the feed line is arranged opposite to and is insulated from the first conductive part, so that the feed line cooperates with the opening to form a slot antenna, and the feed line is configured to be electrically connected with a communication chip to acquire a signal to be radiated from the communication chip. Since the slot antenna in the present disclosure is arranged in the non-display area, so that the optical transmittance of the display area will not be reduced by the slot antenna.

### CROSS-REFERENCE TO RELATED APPLICATION

This application claims the priority of Chinese patent application filed in CNIPA on May 31, 2023, with the application number of 202310637613.5 and the invention name of “DISPLAY PANEL AND DISPLAY APPARATUS”, the entire contents of which are incorporated into this application by reference.

### FIELD

The present disclosure relates to the technical field of display, in particular to a display panel and a display apparatus.

### BACKGROUND

The display apparatus includes a display panel and an antenna. In order to expand the space of the antenna and improve the communication quality, an on-screen antenna scheme of integrating the antenna on the screen of the display panel is proposed in the related art. However, the on-screen antenna scheme leads to the decrease of light transmittance of the display panel.

### SUMMARY

The embodiments of the present disclosure provides a display panel and a display apparatus, and the light transmittance of the display panel is improved when an on-screen antenna solution is adopted.

In order to achieve above object, the embodiment of the present disclosure provides following technical solution.

On one aspect, provided a display panel including a stack of:
a substrate, including a display area and a non-display area;
a first conductive layer, including a first conductive part located in the non-display area, wherein the first conductive part is provided with an opening, and the opening penetrates through the first conductive part along a thickness direction;
a second conductive layer, including a feed line, wherein the feed line is arranged opposite to and is insulated from the first conductive part, so that the feed line cooperates with the opening to form a slot antenna, and the feed line is configured to be electrically connected with a communication chip to acquire a signal to be radiated from the communication chip.

In some embodiments, the first conductive layer is closer to a light-emitting surface of the display panel than the second conductive layer.

In some embodiments, the first conductive layer is located on a side of the substrate facing the light-emitting surface, and the feed line is located on a side of the substrate far from the light-emitting surface.

In some embodiments, the second conductive layer further includes a heat dissipation film located in the display area, and the heat dissipation film is configured to reduce a temperature of the display area.

In some embodiments, an orthogonal projection of the opening on the substrate includes:
a rectangle;
or, an obround;
or, a rectangle and semicircles connected at both ends of the rectangle along a length direction, and a diameter of the semicircle is larger than a width of the rectangle;
or, a rectangle with a variable width.

In some embodiments, the non-display area includes a first edge far away from the display area, and a dimension of the opening along the first edge is l, and a dimension of the opening perpendicular to the first edge is w, and l≥w.

In some embodiments, the feed line includes a feeding part and a connecting part, wherein the connecting part extends in a direction perpendicular to the first edge, one end of the connecting part is electrically connected with the feeding part, and the other end of the connecting part is configured to be electrically connected with the communication chip;
the feeding part is rectangular, and a long edge of the feeding part extends along the first edge;
or, the feeding part is circular;
or, the feeding part is hollowed out inside.

In some embodiments, w≥100 um.

In some embodiments, an edge of the first conductive part close to the first edge is a first side, and a distance between the opening and the first side is greater than or equal to 600 um.

In some embodiments, a plurality of the slot antennas are arranged in the non-display area, and the plurality of slot antennas are arranged at intervals along the first edge, so that the plurality of slot antennas form an antenna array.

In some embodiments, the non-display area includes a first non-display area and a second non-display area, and the antenna array includes a first antenna array and a second antenna array, wherein the first antenna array is located in the first non-display area and the second antenna array is located in the second non-display area; and the slot antenna in the first antenna array is the same as or different from the slot antenna in the second antenna array.

In some embodiments, the display panel includes a light-emitting device and a cathode voltage line, the cathode voltage line is located in the non-display area and electrically connected with a cathode of the light-emitting device, and the cathode voltage line is located in the first conductive layer.

In some embodiments, the first conductive part belongs to the cathode voltage line.

In some embodiments, the second conductive layer is closer to the light-emitting surface of the display panel than the first conductive layer.

In some embodiments, the first conductive layer is provided with an encapsulation layer on a side away from the substrate, and the second conductive layer is located on a side of the encapsulation layer away from the substrate.

In some embodiments, he opening is filled with an optical adhesive or an encapsulation layer.

On the other aspect, provided a display apparatus including the display panel and a control panel, wherein the control panel is provided with a communication chip, and the communication chip is electrically connected with a feed line in the display panel.

In the display panel provided by the embodiments of the present disclosure, the first conductive layer includes a first conductive part located in the non-display area, the first conductive part is provided with an opening penetrating through the first conductive layer in the thickness direction, and the second conductive layer includes a feed line, and the feed line is opposite to and insulated from the first conductive part, so that the opening and the feed line cooperate to form a slot antenna in the non-display area, so that the display apparatus may communicate with external equipment through the slot antenna. Compared with the related art that a gridded metal layer is arranged in the display area, the slot antenna in the embodiments of the present disclosure is arranged in the non-display area, so that the optical transmittance of the display area will not be reduced by the slot antenna.

### BRIEF DESCRIPTION OF THE DRAWINGS

In order to explain the embodiments of the present disclosure or the technical solution in the prior art more clearly, the appended drawings needed to be used in the description of the embodiments or the prior art will be briefly introduced below. Apparently, the appended drawings in the following description are only some embodiments of the present disclosure, and other drawings may be obtained according to these drawings without expenditure of creative labor for persons skilled in the art.

FIG. 1 schematically shows a front view structure of a display apparatus;

FIG. 2 schematically shows a front view of a display panel;

FIG. 3 is a sectional view related to B-B in FIG. 2;

FIG. 4 is a C-direction view of FIG. 3;

FIG. 5 is a sectional view related to D-D in FIG. 4;

FIG. 6 schematically shows a structural diagram of a first conductive part;

FIG. 7 schematically shows another structural diagram of a first conductive part;

FIG. 8 schematically shows another structural diagram of a first conductive part;

FIG. 9 schematically shows another structural diagram of a first conductive part;

FIG. 10 schematically shows a structure diagram of a feed line;

FIG. 11 schematically shows another structural diagram of a feed line;

FIG. 12 schematically shows another structural diagram of a feed line;

FIG. 13 is another C-direction view of FIG. 3;

FIG. 14 is another C-direction view of FIG. 3;

FIG. 15 is another C-direction view of FIG. 3;

FIG. 16 is another C-direction view of FIG. 3;

FIG. 17 is another C-direction view of FIG. 3;

FIG. 18 is an S11 parameter curve obtained by simulation of the slot antenna shown in FIG. 4;

FIG. 19 is a simulation curve area of a peak gain of the slot antenna shown in FIG. 4;

FIG. 20 is a curve of frequency and radiation efficiency;

FIG. 21 is a gain direction diagram of a slot antenna at 26 GHz;

FIG. 22 schematically shows a front view of another display panel;

FIG. 23 schematically shows a front view of another display panel.

### REFERENCE NUMERAL

100—a display apparatus;
110—a display panel;
120—a housing;
111—a display area;
112—a non-display area;
101—a substrate;
102—a first conductive layer;
103—a second conductive layer;
104—a pixel driving circuit;
105—an encapsulation layer;
106—a functional layer;
1—a first conductive part;
2—a feed line;
21—a feeding part;
22—a connecting part;
3—a heat dissipation film;
4—an opening;
5—a organic film layer;
6—a light-emitting device;
10—an antenna array;
11—a first antenna array;
12—a second antenna array.

### DETAILED DESCRIPTION

In the following, the technical solution in the embodiments of the present disclosure will be clearly and completely described with reference to the attached drawings. Apparently, the described embodiments are only a part of the embodiments of the present disclosure, but not the whole embodiment. Based on the embodiments in the present disclosure, all other embodiments obtained by persons skilled in the art without expenditure of creative labor belong to the scope of protection in the present disclosure.

In the embodiments of the present disclosure, the words “first”, “second”, “third” and “fourth” are used to distinguish the same or similar items with basically the same functions and functions, only to clearly describe the technical solution of the embodiments of the present disclosure, and cannot be understood as indicating or implying relative importance or implicitly indicating the number of indicated technical features.

In the embodiments of the present disclosure, the meaning of “multiple” is two or more, and the meaning of “at least one” is one or more, unless otherwise specifically defined.

In the embodiments of the present disclosure, the azimuth or positional relationship indicated by the terms “upper” and “lower” is based on the azimuth or positional relationship shown in the attached drawings, which is only for the convenience of describing the present disclosure and simplifying the description, and does not indicate or imply that the device or element referred to must have a specific orientation, be constructed and operated in a specific orientation, so it cannot be understood as a limitation of the present disclosure.

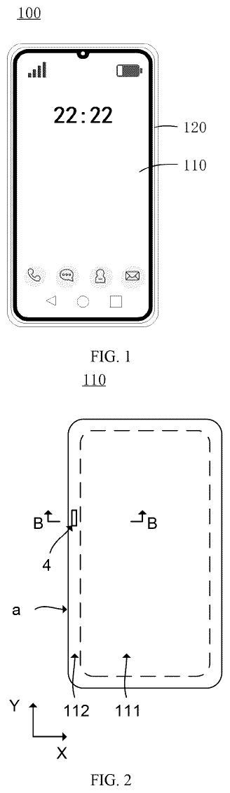

FIG. 1 schematically shows a front view structure of a display apparatus. As shown in FIG. 1, some embodiments of the present disclosure provide a display apparatus 100, which may be any device that displays whether it is moving (e.g., video) or fixed (e.g., still image) and whether it is a text or an image. More specifically, it is contemplated that the embodiments may be implemented in or associated with a variety of electronic devices, such as, but not limited to, a mobile phone, a wireless device, a personal data assistant (PDA), a handheld or portable computer, a GPS receiver/navigator, a camera, an MP4 video player, a video camera, a game console, a watch, a clock, a calculator, a television monitor, a flat panel display, a computer monitor, an automobile display (for example, Odometer displays, etc.), navigators, cockpit controllers and/or displays, displays of camera views (for example, displays of rear-view cameras in vehicles), electronic photographs, electronic billboards or signs, projectors, building structures, packaging and aesthetic structures (for example, displays of images of a piece of jewelry), etc. FIG. 1 illustrates the display apparatus 100 as a mobile phone.

As shown in FIG. 1, the display apparatus 100 includes a housing 120, a display panel 110 and a control panel (not shown) arranged in the housing 120, and the control panel is electrically connected with the display panel 110 to control the display panel 110 to display images.

The display panel 110 may be a Liquid Crystal Display (LCD). The display panel 110 may also be an electroluminescent display panel or a photoluminescence display panel. When the display panel 110 is an electroluminescent display panel, the electroluminescent display panel may be an Organic light-emitting Diode (OLED) display panel or a Quantum Dot light-emitting Diode (QLED) display panel. When the display panel 110 is a photoluminescent display panel, the photoluminescent display apparatus may be a quantum dot light-emitting diode display panel. Some embodiments of the present disclosure are explained by taking the display panel 110 as an Organic light-emitting Diode (OLED) display panel.

The display apparatus 100 also includes an antenna, and a communication chip is arranged on the control panel, and the communication chip is electrically connected with the antenna through a feed line. When working, the antenna receives guided waves from the feed line and converts the guided waves into electromagnetic waves propagating in a free space; Alternatively, the antenna receives electromagnetic waves propagating in the free space and converts the electromagnetic waves into guided waves propagating through the feed line. Thus, the display apparatus 100 may communicate with external devices through the antenna.

With the development of communication technology, communication technology has passed from the first generation mobile communication technology (1G for short), the second generation mobile communication technology (2G for short), the third generation mobile communication technology (3G for short), the fourth generation mobile communication technology (4G for short), and the fifth generation mobile communication technology (5G for short), to the sixth generation mobile communication technology (6G for short). In order to improve the communication capability of the display apparatus 100, the display apparatus 100 may generally be compatible with multiple mobile communication technologies at the same time, for example, the display apparatus 100 is compatible with 2G, 3G, 4G and 5G at the same time.

Because different generations of mobile communication technologies use different frequency bands, and different frequency bands need antennas with different parameters. Therefore, in order to be compatible with a variety of mobile communication technologies, it is necessary to set up a variety of antennas in the display apparatus 100 at the same time, so that the antennas occupy a large space in the electronic equipment. On the other hand, with the miniaturization and narrow bezel of the display apparatus 100, the space for installing an antenna in the display apparatus 100 becomes smaller and smaller.

In order to solve this problem, the related technology proposes an on-screen antenna scheme, that is, an additional gridded metal layer is set on the display panel as an antenna. In order to improve the consistency of display effect in all regions of the display panel, the gridded metal layer should at least cover the display area of the display panel as a whole. However, the gridded metal layer antenna has obvious disadvantages. On the one hand, the gridded metal layer will block some light, which will reduce the light transmittance of the display panel (for example, setting the gridded metal layer as an antenna in some schemes will reduce the optical light transmittance by 5%˜20%); On the other hand, a process difficulty of manufacturing a gridded metal layer is relative high (for example, in some schemes, the width of each trace in the gridded metal layer is only a few microns).

In view of this, in the display panel 110 provided by the embodiments of the present disclosure, a slot antenna is arranged in a non-display area, which does not affect the optical transmittance of the display area and reduces the process difficulty.

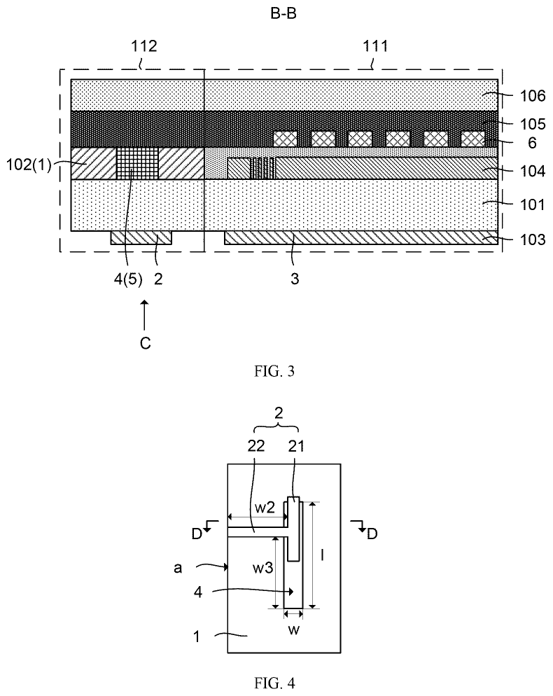

FIG. 2 schematically shows a front view of a display panel. FIG. 3 is a sectional view related to B-B in FIG. 2. As shown in FIG. 3, the display panel 110 includes a substrate 101 and a multilayer film structure stacked on the substrate 101.

The substrate 101 may be a rigid substrate or a flexible substrate, and may be selected and arranged according to actual needs.

Illustratively, the substrate 101 is a rigid substrate. For example, the rigid substrate may be a glass substrate or a PMMA (Polymethyl methacrylate) substrate or the like.

Illustratively, the substrate 101 may be a flexible substrate. For example, the flexible substrate may be a PET (Polyethyleneterephthalate) substrate, a PEN (Polyethylene Naphthalate Two Formic Acid Glycoester) substrate or a PI (Polyimide) substrate.

As shown in FIG. 2 and FIG. 3, the substrate 101 includes a display area 111 and a non-display area 112, and the display area 111 is connected with the non-display area 112. The non-display area 112 may be located on one side, two sides or three sides of the display area 111, or the non-display area 112 may be arranged around the display area 111.

Illustratively, in FIG. 2, an area within a dashed box is the display area 111, and an area outside the dashed box is the non-display area 112. In FIG. 3, an area within a left dashed box is the non-display area 112, and an area within a right dashed box is the display area 111.

Illustratively, the multilayer film structure provided on the substrate 101 may form a plurality of sub-pixels, a plurality of gate lines and a plurality of data lines in the display area 111. A plurality of sub-pixels may be arranged in an array. For example, a plurality of sub-pixel arrays are arranged to form a plurality of sub-pixel rows and a plurality of sub-pixel columns, wherein a plurality of sub-pixels in a sub-pixel row are arranged along a first direction X, and a plurality of sub-pixels in a sub-pixel column are arranged along a second direction Y. Wherein the first direction X and the second direction Y cross each other. An included angle between the first direction X and the second direction Y may be selected and set according to actual needs. Illustratively, the included angle between the first direction X and the second direction Y may be 85°, 88°, 90°, 92° or 95°, etc.

A sub-pixel may include a pixel driving circuit 104 and a light-emitting device 6 electrically connected to the pixel driving circuit 104. When the display panel 110 is in operation, the light-emitting device 6 may emit light under the driving of the pixel driving circuit 104.

Illustratively, the multilayer film structure provided on the substrate 101 forms a scanning circuit and the like in the non-display area 112 for providing a scanning signal for the pixel driving circuit 104.

With continued reference to FIG. 3, the multilayer film structure arranged on the substrate 101 includes a first conductive layer 102 and a second conductive layer 103. The first conductive layer 102 includes a first conductive part 1 located in the non-display area 112, and the first conductive part 1 is provided with an opening 4, and the opening 4 runs through the first conductive layer 102 along a thickness direction (a direction perpendicular to the substrate) of the first conductive part 102. The second conductive layer 103 includes a feed line 2, the feed line 2 is opposite to and is insulated from the first conductive part 1, so that the feed line 2 cooperates with the first conductive part 1 to form a slot antenna.

The first conductive layer 102 and the second conductive layer 103 are made of conductive materials. Illustratively, the first conductive layer 102 and the second conductive layer 103 are metal layers, such as gold and copper. Certainly, the first conductive layer 102 and the second conductive layer 103 may also be semiconductor materials treated by doping process, which is not limited here.

The first conductive layer 102 may also include a second conductive part (not shown in the figure) located in the display area 111, and the second conductive part may be electrically connected with the first conductive part 1 to increase an area of the conductive layer where the opening 4 is located, thereby improving a radiation performance of the slot antenna.

The arrangement of the feed line 2 opposite to the first conductive part 1 means that the feed line 2 and the first conductive part 1 are arranged opposite to each other in the direction perpendicular to the substrate 101. Illustratively, an orthogonal projection of the feed line 2 and the first conductive part 1 on the substrate 101 at least partially overlaps.

The insulating arrangement of the feed line 2 and the first conductive part 1 means that the feed line 2 has no direct electrical connection with the first conductive part 1. Illustratively, a film layer made of an insulating material is provided between the first conductive layer 102 and the second conductive layer 103 to insulate the first conductive part 1 located in the first conductive layer 102 from the feed line 2 located in the second conductive layer 102.

The first end of the feed line 2 cooperates with the first conductive part 1 to form a slot antenna, and the second end of the feed line 2 is configured to be electrically connected with a communication chip to receive a signal to be radiated from the communication chip and convert the signal to be radiated into a guided wave propagating in the feed line 2.

Illustratively, the display apparatus 100 further includes a Flexible Printed Circuit board (FPC), the display panel 110 includes a binding area, and the control panel is provided with a communication chip. One end of the FPC is bound in the binding area by a binding process, and the other end of the FPC is electrically connected with the control board. The second end of the feed line 2 extends to the binding area in the direction parallel to the substrate 101, so that the feed line 2 is electrically connected with the communication chip on the control board by the FPC.

The principle that the feed line 2 cooperates with the first conductive part 1 to radiate electromagnetic waves can refer to the related art, and will not be repeated here.

The opening 4 may be filled with an organic film layer 5. Illustratively, the opening 4 is filled with optical adhesive.

In the display panel 110 provided by the embodiments of the present disclosure, the first conductive layer 102 includes a first conductive part 1 located in a non-display area 112, the first conductive part 1 is provided with an opening 4 penetrating through the first conductive layer 102 in the thickness direction, and the second conductive layer 103 includes a feed line 2, which is opposite to and is insulated from the first conductive part 1, so that the first conductive part 1 and the feed line 2 cooperate to form a slot antenna in the non-display area, so that the display apparatus 100 may communicate with external equipment through the slot antenna. Compared with the related art in which a gridded metal layer is arranged in the display area, the slot antenna in the embodiments of the present disclosure is arranged in the non-display area 112, so that the optical transmittance of the display area 111 will not be reduced by the slot antenna.

Moreover, in the related art, the process difficulty of manufacturing a gridded metal layer in the display area is relative high. However, in the embodiment of the present disclosure, the first conductive part 1 is provided with an opening 4, and the feed line 2 is formed in the second conductive layer 103, so that the first conductive part 1 and the feed line 2 may cooperate to form a slot antenna, which reduces the difficulty of antenna manufacturing.

In the related art, when the display panel does not adopt the on-screen antenna scheme, the display panel includes a substrate and a plurality of conventional conductive layers stacked on the substrate, and the plurality of conventional conductive layers cooperate with each other to form a wiring, a circuit structure, a light-emitting device and the like in the display panel.

The first conductive layer 102 and the second conductive layer 103 of the embodiments of the present disclosure may be separate film layers for forming a slot antenna, that is, the first conductive layer 102 and the second conductive layer 103 do not belong to the conventional conductive layers described above. This can reduce the signal interference between the slot antenna and other circuit structures in the display panel 110 when radiating electromagnetic waves.

Certainly, the first conductive layer 102 and/or the second conductive layer 103 may also belong to the conventional conductive layer described above. On the one hand, there is no need to set an additional conductive layer or only one additional conductive layer in order to form a slot antenna, which reduces the number of film layers of the display panel 110 and makes the display panel 110 thinner. On the other hand, when an additional conductive layer is not required, the process change in manufacturing the display panel 110 is relatively small, and the production cost of the display panel 110 can be reduced.

The display panel 110 may include a cathode voltage line. The cathode of the light-emitting device is electrically connected with the cathode voltage line, and the anode of the light-emitting device may be electrically connected with the pixel driving circuit. When working, the electric signal provided by the pixel driving circuit matches with the electric signal provided by the cathode voltage line to drive the light-emitting device to emit light.

Illustratively, at least part of the cathode voltage line is located in the non-display area 112 and at least partially surrounds the display area 111.

The conductive layer where the cathode voltage line is located may be the first conductive layer 102, that is, the first conductive part 1 and the cathode voltage line are arranged in the same layer, so that there is no need to set an additional conductive layer for forming the first conductive part 1, which reduces the number of film layers of the display panel 110 and makes the display panel 110 thinner. Moreover, when manufacturing the display panel 110, the cathode voltage line and the first conductive part 1 may be formed on the first conductive layer 102 through a patterning process, and the process change is relative small.

The first conductive part 1 may be a part of the cathode voltage line. For example, an opening 4 is opened in a part of the cathode voltage line located in the non-display area 112, and the area surrounding the opening 4 and located in the non-display area 112 in the cathode voltage line is the first conductive part 1, so that the first conductive part 1 cooperates with the feed line 2 to form a slot antenna.

In practical application, the cathode voltage line is usually passed into a constant low-level signal, and the signal is relatively stable. Therefore, when the first conductive part 1 is used as a part of the cathode voltage line, when the first conductive part 1 cooperates with the feed line 2 and radiates electromagnetic waves, it is less affected by the signal in the cathode voltage line, which makes the communication quality of the display apparatus 100 better.

Certainly, the first conductive part 1 may also be independent of the cathode voltage line and disconnected from the cathode voltage line. This can further reduce the interference between the cathode voltage line and the slot antenna.

Compared with the first conductive part 1 being independent of the cathode voltage line, taking the first conductive part 1 as a part of the cathode voltage line makes the area of the first conductive part 1 and the cathode voltage line in the non-display area 112 smaller, thus reducing the area of the non-display area 112 and the width of the display panel 110 frame.

Illustratively, when the first conductive part 1 is a part of the cathode voltage line, the width of the non-display area may be 1 mm.

When the relative positions of the feed line 2 and the first conductive part 1 in the slot antenna are different, the radiation direction of the slot antenna is different. For example, when the feed line 2 is located on the side of the first conductive part 1 far from the light-emitting surface of the display panel 110, the slot antenna radiates electromagnetic waves in the direction close to the light-emitting surface of the display panel 110; When the feed line 2 is located at the side of the first conductive part 1 close to the light-emitting surface of the display panel 110, the slot antenna radiates electromagnetic waves to the side far away from the light-emitting surface of the display panel 110.

The light-emitting surface of the display panel 110 refers to the surface located at the outermost side of the display panel 110 along the direction of light emitted from the display panel 110.

When the first conductive layer 102 is closer to the light-emitting surface of the display panel 110 than the second conductive layer 103, the slot antenna radiates electromagnetic waves in the direction close to the light-emitting surface of the display panel 110. Because the display panel 110 is usually arranged at the outermost side of the display apparatus 100, that is, the light-emitting surface of the display panel 110 is the outermost surface of the display apparatus 100, when electromagnetic waves are radiated in the direction close to the light-emitting surface, the shielding of the display apparatus 100 to electromagnetic waves is smaller, and the communication quality of the display apparatus 100 can be improved.

The gap between the feed line 2 and the first conductive part 1 affects the radiation efficiency of the slot antenna. For example, within a certain gap range, the larger the gap between the feed line 2 and the first conductive part 1, the higher the radiation efficiency. In order to improve the radiation efficiency of the slot antenna, it is necessary to increase the gap between the feed line 2 and the first conductive part 1. The gap between the feed line 2 and the first conductive part 1 refers to a distance between the feed line 2 and the first conductive part 1 in the direction perpendicular to the substrate 101.

The thickness of the substrate 101 in the display panel 110 is relatively thick. Arranging the first conductive layer 102 on one side of the substrate 101 and arranging the second conductive layer 103 on the opposite side of the substrate 101 may increase the gap between the first conductive layer 102 and the second conductive layer 103, that is, increase the gap between the first conductive part 1 and the feed line 2, thus improving the radiation efficiency of the slot antenna.

Illustratively, the thickness of the substrate 101 is 250 um.

It is possible that the first conductive layer 102 may be located on the side of the substrate 101 facing the light-emitting surface, and the second conductive layer 103 may be located on the side of the substrate 101 far away from the substrate. Alternatively, the first conductive layer 102 is located on the side of the substrate 101 far from the light-emitting surface, and the second conductive layer 103 is located on the side of the substrate 101 facing the light-emitting surface.

Certainly, it is also possible that the first conductive layer 102 and the second conductive layer 103 may be arranged on the same side of the substrate 101. At this time, a layer of insulating material or multiple layers of insulating material may be arranged between the first conductive layer 102 and the second conductive layer 103.

The display panel 110 will generate heat during use, resulting in an increase in the temperature of the display panel 110. As shown in FIG. 3, in order to reduce the temperature of the display panel 110, the side of the display panel 110 far from the light-emitting surface is usually provided with a heat dissipation film 3, which is usually made of a metal with good thermal conductivity, such as copper. In operation, the heat dissipation film 3 absorbs the heat generated by the display panel 110 and radiates the absorbed heat to the surrounding environment.

The heat dissipation film 3 may be located in the second conductive layer 103, that is, the heat dissipation film 3 and the feed line 2 are arranged in the same layer. On the one hand, the number of film layers in the display panel 110 is reduced, making the display panel 110 thinner. On the other hand, there is no need to provide an additional conductive layer for forming the feed line 2. When manufacturing the display panel 110, the heat dissipation film 3 and the feed line 2 may be formed by patterning the second conductive layer 103, so that the change of the manufacturing process of the display panel 110 is relatively small and the production cost of the display panel 110 can be reduced.

Moreover, in the related art, when a gridded metal layer is arranged close to the light-emitting surface, it is necessary to open a via hole to electrically connect the gridded metal layer arranged in different layers with the feed line, and the process is complicated; Or, a flexible circuit board is bound to the edge of the gridded metal layer, and the electric connection between the gridded metal layer and the feed line is realized by the flexible circuit board, so that the display panel frame is relatively wide. When the feed line 2 is arranged on the side of the substrate 101 far away from the light-emitting surface, the trace space of the feed line 2 is larger, and the binding of the feed line 2 and the flexible circuit board can be realized in the area far away from the edge of the display panel. Compared with binding the flexible circuit board on the edge of the display panel, the width of the frame is reduced, and there is no need to open a via hole, so the process is simpler.

With continued reference to FIG. 3, a side of the first conductive layer 102 far from the substrate 101 may be provided with an encapsulation layer 105. The encapsulation layer 105 is used to isolate particles such as water and oxygen from the outside to prevent the particles such as water and oxygen from penetrating through the encapsulation layer 105 and corroding the display panel 110.

Illustratively, the part of the encapsulation layer 105 located in the non-display area 112 is covered on the first conductive layer 102, and the part of the encapsulation layer 105 located in the display area 111 is covered on the light-emitting device 6.

Illustratively, a thickness of the encapsulation layer 105 is 20 um.

When the encapsulation layer 105 is provided, the opening 4 may also be filled with the encapsulation layer 105.

The second conductive layer 103 may be located on a side of the encapsulation layer 105 away from the substrate 101.

With continued reference to FIG. 2, the non-display area 112 includes a first side a far away from the display area 111. The dimension of the non-display area 112 perpendicular to the first edge a is the width of the non-display area 112. In order to make the frame of the display apparatus 100 narrower, it is necessary to reduce the width of the non-display area 112.

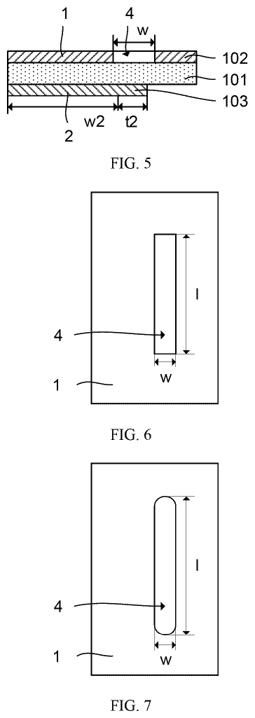

FIG. 4 is a C-direction view of FIG. 3. In FIG. 4, in order to reflect a relative position relationship between the feed line 2 and the opening 4, the substrate 101 and other film structures are removed, and only part of the structures of the first conductive layer 102 and the second conductive layer 103 remain. FIG. 5 is a sectional view related to D-D in FIG. 4.

As shown in FIG. 4 and FIG. 5, a dimension of the opening 4 along the first edge a is l, and a dimension of the opening 4 along the direction perpendicular to the first edge a is w, and l≥w. Since the dimension w of the opening 4 is relatively smaller along the direction perpendicular to the first edge a, the width of the non-display area 112 is relatively narrow, so that the frame of the display apparatus 100 can be relatively narrow.

Illustratively, the opening 4 is elongated as a whole, and the opening 4 extends in the direction of the first edge a.

Optionally, the dimension w of the opening 4 along the direction perpendicular to the first edge a is w≥100 um, so that the radiation performance of the slot antenna is better. For example, when the slot antenna is used in the 5G n258 (24 25 GHz to 27.5 GHZ) frequency band, when w is less than 100 um, the electromagnetic wave signal cannot be radiated normally through the opening 4.

Illustratively, when the slot antenna is used in the 5G n258 (24 25 GHz to 27.5 GHz) frequency band, the dimension l of the opening 4 along the first edge A is about λ/4.

The larger the area of the first conductive part 1, the better the radiation performance of the slot antenna. Ideally, the radiation performance of the slot antenna is the best when the first conductive part 1 is a conductive plane extending infinitely along the direction parallel to the substrate 101.

The side of the first conductive part 1 close to the first edge a is a first side, and the distance between the opening 4 and the first side is greater than or equal to 600 um, so that sufficient space is reserved between the opening 4 and the first side, and the radiation performance of the slot antenna is improved.

The side of the first conductive part 1 far from the first edge a is a second side, and the second side may be electrically connected with other conductive structures to increase the conductive area of the side of the opening 4 far from the first edge a, thereby improving the radiation performance of the slot antenna.

FIG. 6 schematically shows a structural diagram of a first conductive part. As shown in FIG. 6, an orthogonal projection of the opening 4 on the substrate 101 is a rectangle, with the dimension of a long side of the rectangle being l and the dimension of a short side of the rectangle being w.

Illustratively, the dimension w of the short side of the rectangle is 100 um to 200 um, and the dimension l of the long side of the rectangle is λ/4, and λ is a wavelength of the radiated electromagnetic wave. The distance between the rectangular opening 4 and each edge of the first conductive part 1 is schematic and does not represent a specific dimension, that is, the position of the rectangular opening 4 in the first conductive part 1 is not limited.

FIG. 7 schematically shows another structural diagram of a first conductive part. As shown in FIG. 7, an orthogonal projection of the opening 4 on the substrate 101 is an obround. The obround means that both ends of a rectangle along its long side are circular arcs, such as semicircles. The length of the obround is l, and the width of the rectangle is w.

Illustratively, the length l of the obround is λ/4, λ is the wavelength of the radiated electromagnetic wave, and the width w of the obround is 100 um to 200 um. The distance between the obround opening 4 and each edge of the first conductive part 1 is schematic and does not represent a specific dimension, that is, the position of the obround opening 4 in the first conductive part 1 is not limited.

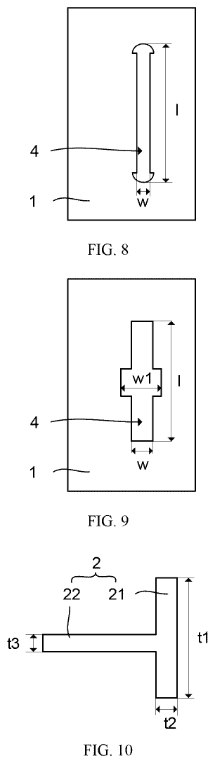

FIG. 8 schematically shows another structural diagram of a first conductive part. As shown in FIG. 8, an orthogonal projection of the opening 4 on the substrate 101 is a combined pattern of multiple patterns, including a rectangle, a semicircle connected at one end of the rectangle and a semicircle connected at the other end of the rectangle, and the diameter of the semicircle is larger than the dimension w in the width direction of the rectangle.

Illustratively, a midpoint of the semicircle is located at ta center line of the rectangle.

Illustratively, the dimension l in the length direction of the opening 4 is λ/4, λ is the wavelength of the radiated electromagnetic wave, and the width dimension w of the opening 4 is 100 um to 200 um. The distance between the opening 4 and each edge of the first conductive part 1 is schematic and does not represent a specific dimension, that is, the position of the opening 4 in the first conductive part 1 is not limited.

FIG. 9 schematically shows another structural diagram of a first conductive part. As shown in FIG. 9, an orthogonal projection of the opening 4 on the substrate 101 is a rectangle with variable width. The rectangle with variable width means that the orthogonal projection of the opening 4 on the substrate 101 includes a plurality of rectangles connected together, and the widths of the rectangles are different. Illustratively, it includes a first rectangle, and a second rectangle and a third rectangle connected at both ends of the first rectangle, wherein the dimension of the first rectangle in the width direction is larger than that of the second rectangle and the third rectangle in the width direction.

Illustratively, the center lines of the first rectangle, the second rectangle and the third rectangle coincide.

Illustratively, the dimension l in the length direction of the opening 4 is λ/4, λ is the wavelength of the radiated electromagnetic wave, the width dimension w1 of the first rectangle is 100 um to 200 um, and the dimensions w of the second rectangle and the third rectangle are smaller than w1. The distance between the opening 4 and each edge of the first conductive part 1 is schematic and does not represent a specific dimension, that is, the position of the opening 4 in the first conductive part 1 is not limited.

Certainly, the projection of the opening 4 on the substrate 101 may also be other regular or irregular patterns, such as a circle, an ellipse, a polygon, etc., which is not limited by the embodiments of the present disclosure.

FIG. 10 schematically shows a structure diagram of a feed line. As shown in FIG. 10, the feed line 2 includes a feeding part 21 and a connecting part 22, the feeding part 21 is configured to cooperate with the first conductive part 1 to radiate electromagnetic waves to the surrounding space, one end of the connecting part 22 is electrically connected with the feeding part 21, and the other end of the connecting part 22 is configured to be electrically connected with a communication chip to acquire a signal to be radiated from the communication chip.

The connecting part 22 may extend in a direction perpendicular to the first edge a. A line width of the connecting part 22 is t3, and the value of the line width t3 is not limited in the embodiments of the present disclosure, and may be flexibly set according to the performance requirements of the slot antenna and the trace space in the actual application process.

With continued Reference to FIG. 10, the feeding part 21 may be rectangular, and the feeding part 21 is vertically connected with the connecting part 22. For example, the connecting part 22 extends in the horizontal direction as shown in the figure, and the feeding part 21 extends in the vertical direction as shown in the figure. The dimension t1 in the length direction, the dimension t2 in the width direction and the line width t3 of the connecting part of the feeding part 21 may be flexibly set according to the performance requirements of the slot antenna.

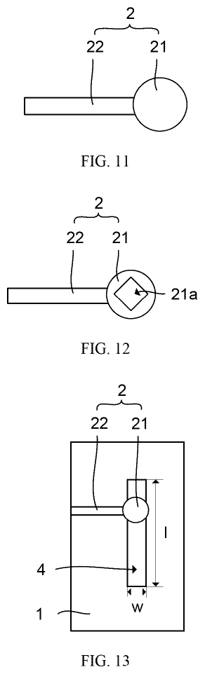

FIG. 11 schematically shows another structural diagram of a feed line. As shown in FIG. 11, the feed line 2 includes a feeding part 21 and a connecting part 22, the feeding part 21 is configured to cooperate with the first conductive part 1 to radiate electromagnetic waves to the surrounding space, one end of the connecting part 22 is electrically connected with the feeding part 21, and the other end of the connecting part 22 is configured to be electrically connected with a communication chip to acquire a signal to be radiated from the communication chip.

The connecting part 22 may extend in a direction perpendicular to the first edge a. The line width of the connecting part 22 is t3, and the value of the line width t3 is not limited in the embodiments of the present disclosure, and may be flexibly set according to the performance requirements of the slot antenna and the trace space in the actual application process.

With continued reference to FIG. 11, the feeding part 21 may be circular.

Illustratively, the center of the feeding part 21 coincides with the center line of the connecting part 22.

FIG. 12 schematically shows another structural diagram of a feed line. As shown in FIG. 12, the feed line 2 includes a feeding part 21 and a connecting part 22, the feeding part 21 is configured to cooperate with the first conductive part 1 to radiate electromagnetic waves to the surrounding space, one end of the connecting part 22 is electrically connected with the feeding part 21, and the other end of the connecting part 22 is configured to be electrically connected with a communication chip to acquire a signal to be radiated from the communication chip.

The connecting part 22 may extend in a direction perpendicular to the first edge a. The line width of the connecting part 22 is t3, and the value of the line width t3 is not limited in the embodiment of the present disclosure, and may be flexibly set according to the performance requirements of the slot antenna and the trace space in the actual application process.

With continued reference to FIG. 12, the feeding part 21 is circular, and the inside of the circular is hollowed out inside.

Illustratively, a quadrangular hollowed-out area is arranged in the circle.

Illustratively, the center of the circle of the feeding part 21 coincides with the center of the quadrangular hollowed-out area.

In the slot antenna in the embodiment of the present disclosure, the shape of the opening 4 in the first conductive part 1 may be any one of the above-mentioned shapes of the opening 4, and the structure of the feed line 2 may also be any one of the above-mentioned structures of the feed line 2. It may be combined flexibly in practical application.

With continued reference to FIG. 4, which is one of the slot antennas formed by combining the first conductive part 1 shown in FIG. 6 and the feed line 2 shown in FIG. 10. In the slot antenna shown in FIG. 4, the center of the feed line 2 does not coincide with the center of the opening 4, that is, a feed mode of the slot antenna is eccentric feed.

Referring to FIG. 4 and FIG. 5, the radiation performance of the slot antenna may be adjusted by adjusting the dimensions of t1, t2 and t3 in the feed line 2 and the relative position of the feed line 2 with the opening 4, such as adjusting the dimensions of w2 and w3.

Certainly, the feed mode of the slot antenna may also be the center feed line, that is, the center of the feed line 2 coincides with the center of the opening 4.

FIG. 18 is a parameter curve S11 obtained by simulation of the slot antenna shown in FIG. 4. As shown in FIG. 5, S11 of the slot antenna is less than −10 dB in the frequency band of 25.1 GHz to 26.1 GHz, and the relative bandwidth reaches 3.8%. FIG. 19 is a simulation curve area of a peak gain of the slot antenna shown in FIG. 4. As shown in FIG. 19, the gain in the 5G n258 frequency band can reach 4.92 dBi and its radiation efficiency can reach 86%.

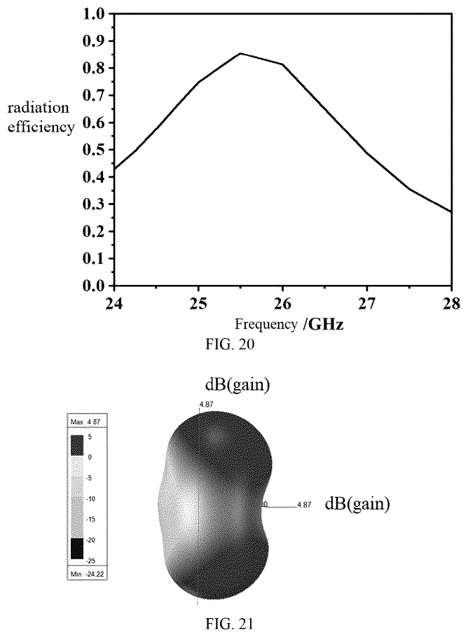

FIG. 20 is a curve of frequency and radiation efficiency, and FIG. 21 is a gain direction diagram of a slot antenna at 26 GHz. FIG. 13 is another C-direction view of FIG. 3. In FIG. 13, the first conductive part 1 of the slot antenna has the structure shown in FIG. 6, and the feed line 2 has the structure shown in FIG. 11. In the slot antenna shown in FIG. 13, because the opening 4 and the feeding part 21 are rounded, the gain varying with frequency becomes relatively smooth, and the bandwidth of the slot antenna may be increased to a certain extent, thus covering more 5G frequency bands.

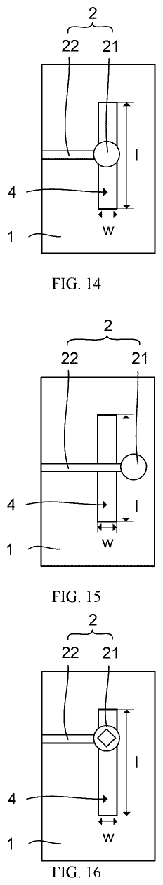

FIG. 14 is another C-direction view of FIG. 3. The difference between the slot antenna shown in FIG. 14 and the slot antenna shown in FIG. 13 is that the slot antenna shown in FIG. 14 adopts the mode of center feeding, that is, the center of the feed line 2 coincides with the center of the opening 4.

FIG. 15 is another C-direction view of FIG. 3. The difference between the slot antenna shown in FIG. 15 and the slot antenna shown in FIG. 14 is that the orthogonal projection of the feeding part 21 on the first conductive part 1 in the slot antenna shown in FIG. 15 does not overlap with the opening 4.

FIG. 16 is another C-direction view of FIG. 3. The difference between the slot antenna shown in FIG. 16 and the slot antenna shown in FIG. 13 is that the feeding part 21 in the slot antenna shown in FIG. 16 adopts the structure shown in FIG. 12.

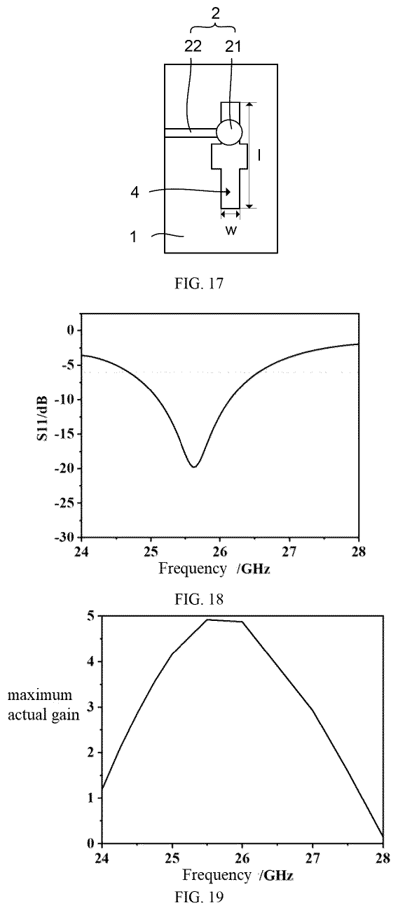

FIG. 17 is another C-direction view of FIG. 3. The difference between the slot antenna shown in FIG. 17 and the slot antenna shown in FIG. 13 is that the opening 4 in the slot antenna shown in FIG. 17 adopts the structure shown in FIG. 9.

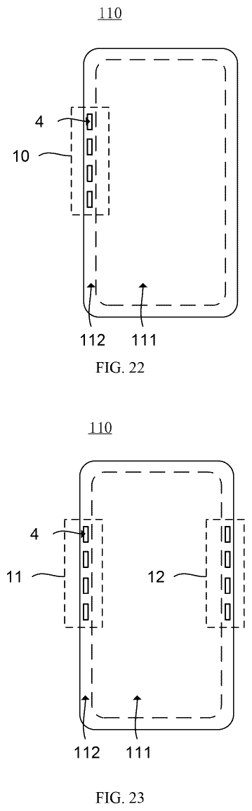

FIG. 22 schematically shows a front view of another display panel. As shown in FIG. 22, a plurality of slot antennas are arranged in the non-display area 112 at intervals along the first edge a, so that the plurality of slot antennas form the antenna array 10. The propagation loss of electromagnetic waves in millimeter wave band in space is usually greater than that in centimeter wave band and decimeter wave band, and the electromagnetic waves in millimeter wave band are also significantly affected by obstructions. Therefore, the antenna gain can be improved by composing a plurality of slot antennas into the antenna array 10, to reduce the propagation loss and reduce the influence caused by obstructions. Moreover, the composed antenna array 10 can appropriately increase the communication distance of the display apparatus 100. At the same time, the antenna array 10 has the ability of beamforming, which can reduce the coverage blind area of the antenna array 10.

FIG. 23 schematically shows a front view of another display panel. As shown in FIG. 23, the non-display area 112 includes a first non-display area and a second non-display area, and the antenna array 10 includes a first antenna array 11 and a second antenna array 12. The first antenna array 11 is located in the first non-display area and the second antenna array 12 is located in the second non-display area.

Illustratively, the area on the left side of the display area 111 in the non-display area 112 is the first non-display area, and the area on the right side of the display area 111 is the second non-display area. Certainly, the first non-display area or the second non-display area may also be located above the display area 111.

The slot antennas in the first antenna array 11 have the same structure, and the slot antennas in the second antenna array 12 have the same structure.

The first antenna array 11 and the second antenna array 12 may be the same or different. The same means that the structure and arrangement of slot antennas in antenna array 10 are the same, and the difference means that the structure and/or arrangement of slot antennas in antenna array 10 are different.

Illustratively, the operating frequency bands of the first antenna array 11 and the second antenna array 12 are different. For example, the first antenna array 11 is used for 4G communication and the second antenna array 12 is used for 5G communication.

Illustratively, in the display panel 110 shown in FIG. 2, FIG. 22 and FIG. 23, at least one antenna array 10 is arranged in the non-display area 112 located on the left, right and upper side of the display area 111, so that the space of the non-display area 112 may be fully utilized and more antenna arrays 10 may be arranged.

With continued reference to FIG. 3, the display panel 110 may further include a functional layer 106 located on the side of the encapsulation layer 105 far from the substrate 101.

Illustratively, the functional layer includes a polarizer, an optical adhesive, and a glass cover plate, and the polarizer, the optical adhesive, and the glass cover plate are successively stacked along the direction away from the substrate 101.

Illustratively, a thickness of the polarizer is 104 um, a thickness of the optical adhesive is 150 um, and a thickness of the glass cover plate is 650 um.

The above is only the specific implementation of the present disclosure, but the protection scope of the present disclosure is not limited to this. Any person skilled in the art can easily think of changes or substitutions within the technical scope disclosed in the present disclosure, which should be included in the protection scope of the present disclosure. Therefore, the scope of protection of the present disclosure should be based on the scope of protection of the claims.

1. A display panel comprising a stack of:
a substrate, comprising a display area and a non-display area;
a first conductive layer, comprising a first conductive part located in the non-display area, wherein the first conductive part is provided with an opening, and the opening penetrates through the first conductive part along a thickness direction;
a second conductive layer, comprising a feed line, wherein the feed line is arranged opposite to and is insulated from the first conductive part, so that the feed line cooperates with the opening to form a slot antenna, and the feed line is configured to be electrically connected with a communication chip to acquire a signal to be radiated from the communication chip.

2. The display panel according to claim 1, wherein the first conductive layer is closer to a light-emitting surface of the display panel than the second conductive layer.

3. The display panel according to claim 2, wherein the first conductive layer is located on a side of the substrate facing the light-emitting surface, and the feed line is located on a side of the substrate far from the light-emitting surface.

4. The display panel according to claim 3, wherein the second conductive layer further comprises a heat dissipation film located in the display area, and the heat dissipation film is configured to reduce a temperature of the display area.

5. The display panel according to claim 1, wherein an orthogonal projection of the opening on the substrate comprises:
a rectangle;
or, an obround;
or, a rectangle and semicircles connected at both ends of the rectangle along a length direction, and a diameter of the semicircle is larger than a width of the rectangle;
or, a rectangle with a variable width.

6. The display panel according to claim 1, wherein the non-display area comprises a first edge far away from the display area, and a dimension of the opening along the first edge is 1, and a dimension of the opening along a direction perpendicular to the first edge is w, and l≥w.

7. The display panel according to claim 6, wherein the feed line comprises a feeding part and a connecting part, wherein the connecting part extends in a direction perpendicular to the first edge, one end of the connecting part is electrically connected with the feeding part, and the other end of the connecting part is configured to be electrically connected with the communication chip;
the feeding part is rectangular, and a long edge of the feeding part extends along the first edge;
or, the feeding part is circular;
or, the feeding part is hollowed out inside.

8. The display panel according to claim 6, wherein w≥100 um.

9. The display panel according to claim 6, wherein an edge of the first conductive part close to the first edge is a first side, and a distance between the opening and the first side is greater than or equal to 600 um.

10. The display panel according to claim 6, wherein a plurality of the slot antennas are arranged in the non-display area, and the plurality of slot antennas are arranged at intervals along the first edge, so that the plurality of slot antennas form an antenna array.

11. The display panel according to claim 10, wherein the non-display area comprises a first non-display area and a second non-display area, and the antenna array comprises a first antenna array and a second antenna array, wherein the first antenna array is located in the first non-display area and the second antenna array is located in the second non-display area; and the slot antenna in the first antenna array is the same as or different from the slot antenna in the second antenna array.

12. The display panel according to claim 1, wherein the display panel comprises a light-emitting device and a cathode voltage line, the cathode voltage line is located in the non-display area and electrically connected with a cathode of the light-emitting device, and the cathode voltage line is located in the first conductive layer.

13. The display panel according to claim 12, wherein the first conductive part belongs to the cathode voltage line.

14. The display panel according to claim 1, wherein the second conductive layer is closer to the light-emitting surface of the display panel than the first conductive layer.

15. The display panel according to claim 14, wherein the first conductive layer is provided with an encapsulation layer on a side away from the substrate, and the second conductive layer is located on a side of the encapsulation layer away from the substrate.

16. The display panel according to claim 1, wherein the opening is filled with an optical adhesive or an encapsulation layer.

17. A display apparatus comprising a display panel according to claim 1 and a control panel, wherein the control panel is provided with a communication chip, and the communication chip is electrically connected with a feed line in the display panel.
